(19) United States
(12) Patent Application Publication
(10) Pub. No.: US 2023/0019366 A1
(43) Pub. Date: Jan. 19, 2023

(54) SEMICONDUCTOR STRUCTURE AND METHOD FOR FORMING SAME

(71) Applicant: CHANGXIN MEMORY TECHNOLOGIES, INC., Heifei (CN)

(72) Inventor: Haibo CHEN, Hefei (CN)

(21) Appl. No.: 17/952,261

(22) Filed: Sep. 25, 2022

Related U.S. Application Data
(63) Continuation of application No. PCT/CN2022/076280, filed on Feb. 15, 2022.

(30) Foreign Application Priority Data
Jul. 21, 2021 (CN) 202110825385.5

(51) Int. Cl. H01L 21/28; H01L 21/02; H01L 21/8234; H01L 21/67; H01L 21/762

(52) U.S. Cl. CPC H01L 21/28202; H01L 21/02518; H01L 21/823462; H01L 21/67075; H01L 21/762

(57) ABSTRACT

A method for forming a semiconductor structure includes: providing a substrate including a first region and a second region; forming a first initial gate dielectric layer in the first region and forming a second initial gate dielectric layer in the second region; injecting doped elements into the first initial gate dielectric layer and the second initial gate dielectric layer; and thinning the first initial gate dielectric layer and the second initial gate dielectric layer, to form a first gate dielectric layer and a second gate dielectric layer, where a thickness of the first gate dielectric layer is greater than a thickness of the second gate dielectric layer. A negative-bias temperature instability (NBTI) effect is improved for a first transistor and a second transistor.

### CROSS-REFERENCE TO RELATED APPLICATION

The present disclosure is a continuation of PCT/CN2022/076280, filed on Feb. 15, 2022, which claims priority to Chinese Patent Application No. 202110825385.5, titled “SEMICONDUCTOR STRUCTURE AND METHOD FOR FORMING SAME” and filed on, Jul. 21, 2021, the entire contents of which are incorporated herein by reference.

### TECHNICAL FIELD

The present disclosure relates to the field of semiconductor fabrication technology, and more particularly, to a semiconductor structure and a method for forming the same.

### BACKGROUND

As a semiconductor structure commonly used in electronic devices such as computers, Dynamic Random Access Memory (DRAM) comprises a plurality of memory cells, and each of the memory cells typically includes a transistor and a capacitor. A gate of the transistor is electrically connected to a word line, a source of the transistor is electrically connected to a bit line, and a drain of the transistor is electrically connected to the capacitor. A word line voltage of the word line can control on or off of the transistor, such that data information stored in the capacitor can be read or written into the capacitor by means of the bit line.

However, for a p-channel metal oxide semiconductor (PMOS) in a semiconductor structure such as the DRAM, as a feature size of an integrated circuit shrinks, a gate electric field increases, and an operating temperature of a PMOS device increases, device parameters (such as a threshold voltage, a transconductance, and a drive current) degrade, leading to appearance of a negative-bias temperature instability (NBTI) effect. The NBTI effect has serious adverse impacts on service life and performance reliability of the semiconductor structure.

Therefore, how to reduce the impacts of the NBTI effect and improve the service life and the performance reliability of the semiconductor structure is a technical problem to be solved urgently at present.

### SUMMARY

The present disclosure provides a semiconductor structure and a method for forming the same.

According to some embodiments, the present disclosure provides a method of forming a semiconductor structure, including: providing a substrate, wherein the substrate comprises a first region configured for forming a first transistor and a second region configured for forming a second transistor; forming a first initial gate dielectric layer on a surface of the first region and forming a second initial gate dielectric layer on a surface of the second region; injecting doped elements into the first initial gate dielectric layer and the second initial gate dielectric layer; and thinning the first initial gate dielectric layer and the second initial gate dielectric layer, to form a first gate dielectric layer and a second gate dielectric layer, wherein a thickness of the first gate dielectric layer is greater than a thickness of the second gate dielectric layer.

According to some embodiments, the present disclosure also provides a semiconductor structure, which is formed by means of the method for forming the semiconductor structure described in any one of the above embodiments.

### BRIEF DESCRIPTION OF THE DRAWINGS

FIG. 1 is a flowchart of a method for forming a semiconductor structure according to an embodiment of the present disclosure; and

FIGS. 2A to 21 are schematic cross-sectional views showing main processes in a process of forming the semiconductor structure according to an embodiment of the present disclosure.

### DETAILED DESCRIPTION

Embodiments of a semiconductor structure and a method for forming the same provided by the present disclosure will be described in detail below with reference to the accompanying drawings.

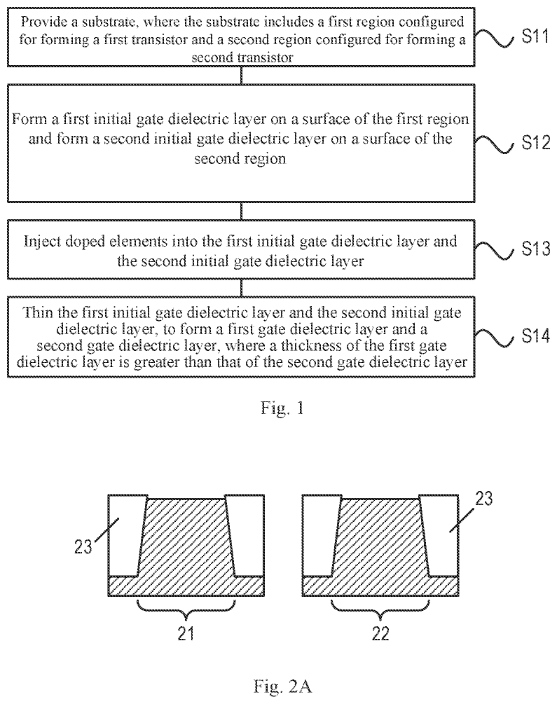

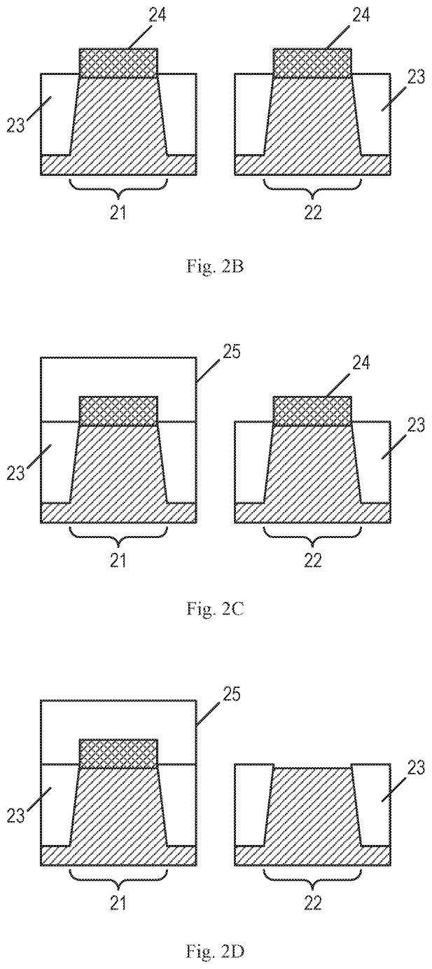

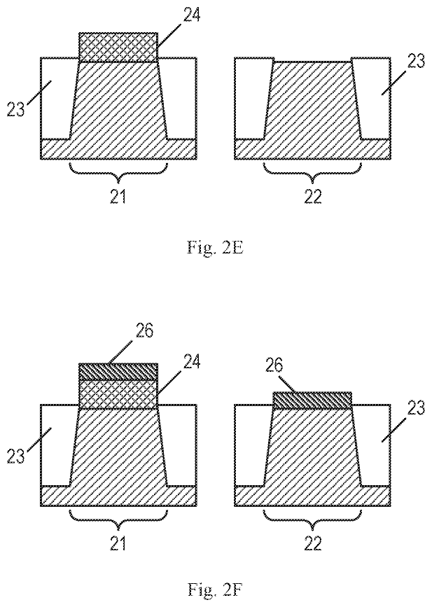

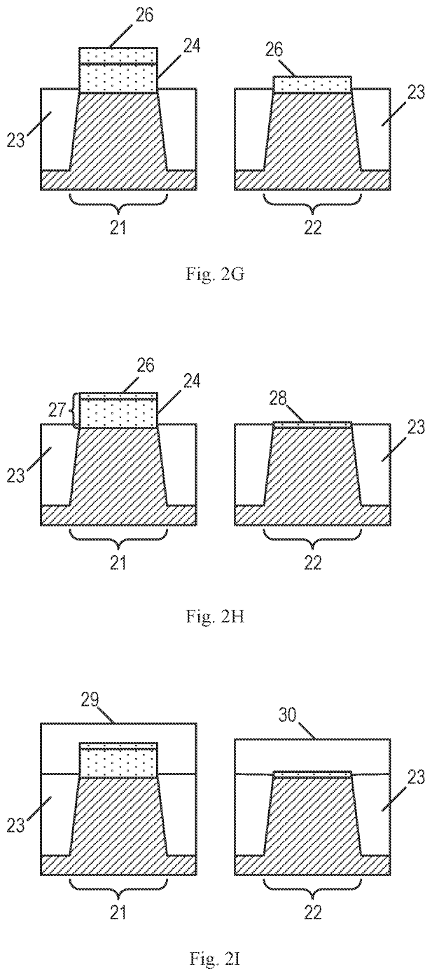

The embodiments provide a method for forming a semiconductor structure. FIG. 1 is a flowchart of the method for forming the semiconductor structure according to an embodiment of the present disclosure; and FIGS. 2A to 21 are schematic cross-sectional views showing main processes in a process of forming the semiconductor structure according to an embodiment of the present disclosure. As shown in FIG. 1 and FIGS. 2A to 2T, the method for forming the semiconductor structure includes following steps.

Step S11, providing a substrate, where the substrate includes a first region 21 configured for forming a first transistor and a second region 22 configured for forming a second transistor, as shown in FIG. 2A.

In some embodiments, the substrate may be, but is not limited to, a silicon substrate. This embodiment is described by taking an example where the substrate 20 is the silicon substrate. In other examples, the substrate 10 may be a semiconductor substrate such as gallium nitride, gallium arsenide, gallium carbide, silicon carbide, or silicon on insulator (SOI). The substrate has the first region 21 and the second region 22, where the first region 21 is isolated from a surrounding device region by means of a shallow trench isolation structure 23, and the second region 22 is also isolated from the surrounding device region by means of the shallow trench isolation structure 23. A material of the shallow trench isolation structure 23 may be, but is not limited to, an oxide material. The first region 21 and the second region 22 may be adjacent to each other, or may be separated by multiple device regions. The first transistor and the second transistor may be transistors having different threshold voltages. For example, the threshold voltage of the first transistor is greater than that of the second transistor.

In some embodiments, the first transistor and the second transistor are both p-channel metal oxide semiconductor (PMOS) transistors.

Step S12, forming a first initial gate dielectric layer on a surface of the first region 21 and forming a second initial gate dielectric layer on a surface of the second region 22, as shown in FIG. 2F.

In some embodiments, the step of forming the first initial gate dielectric layer on the surface of the first region 21 and forming the second initial gate dielectric layer on the surface of the second region 22 includes: forming a first dielectric layer 24 on the surface of the first region 21; and forming a second dielectric layer 26 on a surface of the first dielectric layer 24 and on the surface of the second region 22, where the first dielectric layer 24 and the second dielectric layer 26 positioned on the surface of the first dielectric layer 24 jointly function as the first initial gate dielectric layer, and the second dielectric layer 26 positioned on the surface of the second region 22 functions as the second initial gate dielectric layer.

In some embodiments, the step of forming the first dielectric layer 24 on the surface of the first region 21 includes: depositing a first dielectric material on the surface of the first region 21 and on the surface of the second region 22, to form the first dielectric layer 24 covering the first region 21 and the second region 22, as shown in FIG. 2B; and removing the first dielectric layer 24 covering the surface of the second region 22, as shown in FIG. 2E.

In some embodiments, the step of removing the first dielectric layer 24 covering the surface of the second region 22 includes: forming a barrier layer 25 on the substrate, where the barrier layer 25 covers the first dielectric layer 24 on the surface of the first region 21, as shown in FIG. 2C; removing the first dielectric layer 24 covering the surface of the second region 22, as shown in FIG. 2D; and removing the barrier layer 25, as shown in FIG. 2E.

In some embodiments, after the surface of the first region 21 and the surface of the second region 22 of the substrate are cleaned, the first dielectric layer 24 may be formed on the surface of the first region 21 and on the surface of the second region 22 by means of chemical vapor deposition, physical vapor deposition, atomic layer deposition or in-situ steam generation (ISSG), as shown in FIG. 2B. A material of the first dielectric layer 24 may be, but not limited to, an oxide material (such as silicon dioxide). To enable the thickness of the first gate dielectric layer formed subsequently to reach a first preset thickness, thereby ensuring that electrical performance of the first transistor formed finally is not adversely affected, the thickness of the first dielectric layer 24 may be appropriately increased. The thickness of the first dielectric layer 24 may be adjusted depending on actual needs, for example, depending on the thickness of the first gate dielectric layer needing to be formed and types of employed deposition processes.

Next, a photoresist material is deposited on the first dielectric layer 24 in the first region 21 to form the barrier layer 25 such that the first dielectric layer 24 on the second region 22 is exposed, as shown in FIG. 2C. Next, the first dielectric layer 24 positioned on the second region 22 is removed by means of a dry etching process or a wet etching process, such that the surface of the second region 22 of the substrate is exposed, as shown in FIG. 2D. After the barrier layer 25 is removed, a structure as shown in FIG. 2E is obtained.

Next, the second dielectric layer 26 is deposited on the surface of the second region 22 and on the surface of the remaining first dielectric layer 24 by means of chemical vapor deposition, physical vapor deposition or atomic layer deposition, to obtain a structure as shown in FIG. 2F. To enable the thickness of the second gate dielectric layer formed subsequently to reach a second preset thickness, thereby ensuring that electrical performance of the second transistor formed finally is not adversely affected, the thickness of the second dielectric layer 26 may be appropriately increased. The thickness of the second dielectric layer 26 may be adjusted depending on actual needs, for example, depending on the thickness of the second gate dielectric layer needing to be formed and types of employed deposition processes.

In other embodiments, those skilled in the art can also directly deposit the first dielectric layer 24 only on the surface of the first region 21 according to actual needs, thereby further simplifying the formation process of the semiconductor structure.

Reference is made in this embodiment by taking an example where the second dielectric layer 26 is simultaneously deposited on the surface of the second region 22 and on the surface of the remaining first dielectric layer 24. In other embodiments, a person skilled in the art may further deposit and form the second dielectric layer 26 only on the surface of the second region 22 according to actual needs. In this case, the thickness of the first dielectric layer 24 needs to be accordingly increased.

In some embodiments, the material of the first dielectric layer 24 is the same as the material of the second dielectric layer 26.

In some embodiments, both the material of the first dielectric layer 24 and the material of the second dielectric layer 26 may be oxide materials such as silicon dioxide.

In other embodiments, the material of the first dielectric layer 24 may also be different from the material of the second dielectric layer 26.

To form the first transistor and the second transistor having different threshold voltages, in some embodiments, the thickness of the first dielectric layer 24 is greater than that of the second dielectric layer 26.

Step S13: injecting doped elements into the first initial gate dielectric layer and the second initial gate dielectric layer.

In some embodiments, injection of the doped elements can reduce electric leakage of a first gate and a second gate formed subsequently, and can effectively prevent conductive particles in the first gate and the second gate from diffusing into the substrate. The doped element may be, but are not limited to, nitrogen.

When the doped element is nitrogen, in some embodiments, the step of injecting the doped elements into the first initial gate dielectric layer and the second initial gate dielectric layer includes: injecting nitrogen into the first initial gate dielectric layer and the second initial gate dielectric layer by means of a remote plasma nitridation (RPN) process.

In some embodiments, after a structure shown in FIG. 2F is formed, nitrogen may be injected from a top surface of the first initial gate dielectric layer (that is, a surface of the first initial gate dielectric layer away from the substrate) and a top surface of the second initial gate dielectric layer (that is, a surface of the second initial gate dielectric layer away from the substrate) by means of the remote plasma nitridation process. That is, nitrogen is injected into the first dielectric layer 24 on the first region 21 and the second dielectric layer 26, and nitrogen is injected into the second dielectric layer 26 on the second region 22, to obtain a structure shown in FIG. 2G.

Step S14: thinning the first initial gate dielectric layer and the second initial gate dielectric layer, to form a first gate dielectric layer 27 and the second gate dielectric layer 28, where a thickness of the first gate dielectric layer 27 is greater than that of the second gate dielectric layer 28, as shown in FIG. 2H.

In some embodiments, the thicknesses of the first initial gate dielectric layer and the second initial gate dielectric layer formed before doping are increased, and under a condition that an injection depth and/or injection amount of the doped elements remain unchanged, a concentration of the doped elements on a bottom surface of the first initial gate dielectric layer (that is, a surface of the first initial gate dielectric layer in contact with the substrate) and the concentration of the doped elements on a bottom surface of the second initial gate dielectric layer (that is, a surface of the second initial gate dielectric layer in contact with the substrate) can be reduced, thereby reducing a negative-bias temperature instability (NBTI) effect. In addition, thinning the first initial gate dielectric layer and the second initial gate dielectric layer can enable the first gate dielectric layer 27 to reach the first preset thickness and the second gate dielectric layer 28 to reach the second preset thickness. That is, it does not cause increase of the thickness of the first gate dielectric layer 27 and the thickness of the second gate dielectric layer 28.

In some embodiments, the step of thinning the first initial gate dielectric layer and the second initial gate dielectric layer includes: removing part of the first initial gate dielectric layer and part of the second initial gate dielectric layer by means of a wet etching process, to form the first gate dielectric layer 27 having a first thickness and the second gate dielectric layer 28 having a second thickness.

In some embodiments, the step of removing part of the first initial gate dielectric layer and part of the second initial gate dielectric layer by means of the wet etching process includes: removing part of the second dielectric layer 26 in the first initial gate dielectric layer and part of the second initial gate dielectric layer by means of the wet etching process.

In some embodiments, part of the second dielectric layer in the first initial gate dielectric layer and part of the second initial gate dielectric layer may be removed by means of a cleaning process, and a remaining part of the first dielectric layer 24 and a remaining part of the second dielectric layer 26 retained on the surface of the first region 21 together function as the first gate dielectric layer 27. In addition, by means of the cleaning process, the second dielectric layer 26 having part of the thickness on the second region 22 is removed, and the second dielectric layer 26 retained on the second region 22 functions as the second gate dielectric layer 28.

In some embodiments, the doped elements are not provided on the surface of the first gate dielectric layer 27 in contact with the substrate; and the doped elements are not provided on the surface of the second gate dielectric layer 28 in contact with the substrate.

In some embodiments, by adjusting the thickness of the first dielectric layer 24 and the thickness of the second dielectric layer 26, the doped elements are not provided on the surface of the finally formed first gate dielectric layer 27 in contact with the substrate, and the doped elements are not provided on the surface of the second gate dielectric layer 28 in contact with the substrate, thereby further improving the reliability of the NBTI effect.

In some embodiments, after forming the first gate dielectric layer 27 and the second gate dielectric layer 28, the method further includes: forming a first gate 29 on a surface of the first gate dielectric layer 27 and forming a second gate 30 on a surface of the second gate dielectric layer 28.

In some embodiments, the step of forming the first gate 29 on the surface of the first gate dielectric layer 27 and forming the second gate 30 on the surface of the second gate dielectric layer 30 includes: depositing a conductive material on the surface of the first gate dielectric layer 27 and on the surface of the second gate dielectric layer 28, and simultaneously forming the first gate 29 and the second gate 30.

The conductive material may be, but is not limited to, doped polysilicon material.

According to some embodiments, the present disclosure also provides a semiconductor structure, which is formed by means of the method for forming the semiconductor structure described in any one of the above embodiments.

In the semiconductor structure and the method for forming the same provided in the embodiments of the present disclosure, the thicknesses of the first initial gate dielectric layer and the thickness of the second initial gate dielectric layer are increased, and after the doped elements are injected into the first initial gate dielectric layer and the second initial gate dielectric layer, the first initial gate dielectric layer and the second initial gate dielectric layer are thinned, to ensure that the injected doped elements are concentrated on the surface of the first gate dielectric layer and on the surface of the second gate dielectric layer. In this way, a concentration of the doped elements on the bottom surface of the first gate dielectric layer and on the bottom surface of the second gate dielectric layer is effectively reduced, the NBTI effect is improved for the first transistor and the second transistor, and the service life and the performance reliability of the semiconductor structure are improved.

What is mentioned above merely refers to some embodiments of the present disclosure. It shall be pointed out that to those of ordinary skill in the art, various improvements and embellishments may be made without departing from the principle of the present disclosure, and these improvements and embellishments are also deemed to be within the scope of protection of the present disclosure.

What is claimed is:

1. A method for forming a semiconductor structure, comprising:
providing a substrate, wherein the substrate comprises a first region configured for forming a first transistor and a second region configured for forming a second transistor;
forming a first initial gate dielectric layer on a surface of the first region and forming a second initial gate dielectric layer on a surface of the second region;
injecting doped elements into the first initial gate dielectric layer and the second initial gate dielectric layer; and
thinning the first initial gate dielectric layer and the second initial gate dielectric layer, to form a first gate dielectric layer and a second gate dielectric layer, wherein a thickness of the first gate dielectric layer is greater than a thickness of the second gate dielectric layer.

2. The method for forming the semiconductor structure according to claim 1, wherein the forming the first initial gate dielectric layer on the surface of the first region and forming the second initial gate dielectric layer on the surface of the second region comprises:
forming a first dielectric layer on the surface of the first region; and
forming a second dielectric layer on a surface of the first dielectric layer and on the surface of the second region, wherein the first dielectric layer and the second dielectric layer positioned on the surface of the first dielectric layer jointly function as the first initial gate dielectric layer, and the second dielectric layer positioned on the surface of the second region functions as the second initial gate dielectric layer.

3. The method for forming the semiconductor structure according to claim 2, wherein the forming the first dielectric layer on the surface of the first region comprises:
depositing a first dielectric material on the surface of the first region and on the surface of the second region, to form the first dielectric layer covering the first region and the second region; and
removing the first dielectric layer covering the surface of the second region.

4. The method for forming the semiconductor structure according to claim 3, wherein the removing the first dielectric layer covering the surface of the second region comprises:
forming a barrier layer on the substrate, wherein the barrier layer covers the first dielectric layer positioned on the surface of the first region;
removing the first dielectric layer covering the surface of the second region; and
removing the barrier layer.

5. The method for forming the semiconductor structure according to claim 2, wherein a material of the first dielectric layer is the same as a material of the second dielectric layer.

6. The method for forming the semiconductor structure according to claim 2, wherein both a material of the first dielectric layer and a material of the second dielectric layer are oxide materials.

7. The method for forming the semiconductor structure according to claim 2, wherein a thickness of the first dielectric layer is greater than a thickness of the second dielectric layer.

8. The method for forming the semiconductor structure according to claim 1, wherein the injecting the doped elements into the first initial gate dielectric layer and the second initial gate dielectric layer comprises:
injecting nitrogen into the first initial gate dielectric layer and the second initial gate dielectric layer by means of a remote plasma nitridation process.

9. The method for forming the semiconductor structure according to claim 1, wherein the thinning the first initial gate dielectric layer and the second initial gate dielectric layer comprises:
removing part of the first initial gate dielectric layer and part of the second initial gate dielectric layer by means of a wet etching process, to form a first gate dielectric layer having a first thickness and a second gate dielectric layer having a second thickness.

10. The method for forming the semiconductor structure according to claim 9, wherein the removing part of the first initial gate dielectric layer and part of the second initial gate dielectric layer by means of the wet etching process comprises:
removing part of the second dielectric layer in the first initial gate dielectric layer and part of the second initial gate dielectric layer by means of the wet etching process.

11. The method for forming the semiconductor structure according to claim 1, wherein the doped elements are not provided on a surface of the first gate dielectric layer in contact with the substrate; and
the doped elements are not provided on a surface of the second gate dielectric layer in contact with the substrate.

12. The method for forming the semiconductor structure according to claim 1, wherein after forming the first gate dielectric layer and the second gate dielectric layer, the method further comprises:
forming a first gate on a surface of the first gate dielectric layer, and forming a second gate on a surface of the second gate dielectric layer.

13. The method for forming the semiconductor structure according to claim 12, wherein the forming the first gate on the surface of the first gate dielectric layer and forming the second gate on the surface of the second gate dielectric layer comprises:
depositing a conductive material on the surface of the first gate dielectric layer and on the surface of the second gate dielectric layer, and simultaneously forming the first gate and the second gate.

14. The method for forming the semiconductor structure according to claim 1, wherein both the first transistor and the second transistor are p-channel metal oxide semiconductor (PMOS) transistors.

15. A semiconductor structure, the semiconductor structure being formed by means of the method for forming the semiconductor structure according to claim 1.
